(19) United States
(12) Patent Application Publication
(10) Pub. No.: US 2017/0200848 A1
(43) Pub. Date: Jul. 13, 2017

(54) COMPOUND KOHLER SOLAR CONCENTRATOR WITH OPTIONAL SPECTRUM SPLITTING PHOTOVOLTAIC APPARATUS

(71) Applicant: LIGHT PRESCRIPTIONS INNOVATORS, LLC, Altadena, CA (US)

(72) Inventors: PABLO BENITEZ, Madrid (ES); JUAN CARLOS MINANO, Madrid (ES); RUBEN MOHEDANO, Madrid (ES); WAQIDI FALICOFF, Talent, OR (US)

(21) Appl. No.: 15/316,736

(22) PCT Filed: Jun. 9, 2015
(86) PCT No.: PCT/US2015/034905

§ 371 Date: Dec. 6, 2016

Related U.S. Application Data
(60) Provisional application No. 61/997,782, filed on Jun. 9, 2014.

(51) Int. Cl. H01L 31/054; H01L 31/052

(52) U.S. Cl. CPC H01L 31/0543; H01L 31/0547; H01L 31/052; H01L 31/0549

(57) ABSTRACT

A high concentration photovoltaic device has a Fresnel lens having a front side and a back side, which may be mounted on a cover plate, and a mirror behind the Fresnel lens and facing the Fresnel lens. A secondary lens is unitary with the Fresnel lens and facing the mirror, and is typically on the inside of the cover plate in the center of the Fresnel lens. A photovoltaic cell in front of the secondary lens faces the mirror through the secondary lens. An additional focusing lens may be provided in front of the mirror. Two optical elements of said device form a Köhler integrator between a remote source, usually the sun, in front of the device and the photovoltaic cell as a target. The mirror may be spectrally selective, with a secondary photovoltaic cell behind the mirror. Additional photovoltaic cells to collect unfocused light may surround the mirror.

### CROSS REFERENCE TO RELATED APPLICATIONS

Priority is hereby claimed to U.S. Provisional Patent Application No. 61/997,782 filed Jun, 9, 2014, entitled Compound Fresnel Solar Concentrator, which is incorporated by reference herein in its entirety.

This patent application references the following earlier U.S. patents and applications which are incorporated herein in their entirety: U.S. Pat. No. 8,000,018 issued Aug. 16, 2011 to Benitez et al for “Köhler concentrator” and related US Publication 2010/0123954 A1; U.S. patent application Ser. No. 12/957,826 filed on Nov. 23, 2010 by Miñano et al for “On-Window Solar-Cell Heat Spreader” and related PCT Publication WO 2011/066286 A2; U.S. patent application Ser. No. 12/622,664 filed on Nov. 20, 2009 by Benitez et al for “Photovoltaic Concentrator with Auxiliary Cells Collecting Diffuse Radiation” and related US Publication 2010/0126556 A1; U.S. patent application Ser. No. 12/766,298 filed on Apr. 23, 2010 by Benitez et al for “Photovoltaic Device” and related US Publication 2010/0269885; U.S. Pat. No. 8,094,393 issued Jan. 10, 2012 to Miñano and Benitez for “Reflectors Made of Linear Grooves” and related US Publication 2010/0002320 A1.

### TECHNICAL FIELD

The present invention relates generally to the concentration or collimation of light, and especially to photovoltaic solar energy.

### BACKGROUND OF THE INVENTION

High concentration photovoltaic solar concentrators need to be pointed directly at the sun to achieve maximum efficiency. Even slight errors in tracking will degrade their performance, and large errors will result in a failed system. As the trackers used are not perfect, it is therefore important for the concentrator to have a good “acceptance angle”. The acceptance angle is the tracking angular deviation from a perfect alignment with the Sun for which the concentrator is still providing most of its expected power. This is usually rated at 90% of the power generated when the concentrator is in perfect alignment with the Sun.

The higher the acceptance angle: the more relaxed the tolerance for the tracker's accuracy for pointing at the Sun; the more relaxed the tolerances for the assembly of the components in a solar concentrator module; and the more relaxed the tolerances for the assembly of an array of modules onto the tracker. Also, the higher the acceptance angle, the less susceptible the system is to loss of power when the modules on the tracker flutter, from winds or a sag of the modules (due to gravity). This issue is especially a concern for systems having a very large array of modules on a tracker.

All tracking, alignment, assembling and manufacturing tolerances can be expressed in terms of the acceptance angle that they consume. It is important that these tolerances don't exhaust the available acceptance angle because in this case, any extra tolerance will cause a loss of efficiency. This is why it is very important to have an acceptance angle budget as big as possible.

There are different types of optical architectures used for high concentration photovoltaic (HCPV) concentrators. Each type has a unique relationship between acceptance angle and concentration. This relationship is referred to as the Concentration Acceptance-Angle Product (CAP), given as:

CAP=\sqrt{C_{g}}×sin α

Where, C_{g} is the concentration and ±α is the acceptance angle. This acceptance angle is the available budget. The practical CPV array will have a smaller acceptance angle for tracking errors because in general most of the budget has been consumed in manufacturing tolerances. The CAP is almost constant for a given optical architecture, no matter the particular C_{g} used. Then, maximizing a is the key to the success of any HCPV system, especially when it is scaled from a single module to an array of modules on a tracker.

HCPV systems are designed for high solar concentration. This allows the use of smaller solar cells to achieve the same power output. The type of solar cells used in HCPV systems, typically high-performance multi junction cells, are one of the most expensive components in the system, and reducing the size of the solar cell and/or the number of solar cells in the system helps to reduce cost. Maintaining a high acceptance angle at these higher concentrations is only possible for architectures having a high CAP.

Optical systems that only have one optical element, such as a single lens or a single reflector, have a low CAP. Adding a secondary optical element (SOE) increases the CAP. Depending on the design, the SOE can also facilitate cell electrical and moisture isolation, which can help simplify assembly and, thereby, reduce costs.

The solar cells used in HCPV systems have very good efficiency at converting sunlight into electricity, some in the low 40% range. This still means that the majority of the sunlight is converted to heat, and dissipating this heat is very important because the cooler the solar cells, the more efficient the system, and the better the system is at dissipating heat the higher its efficiency. A novel approach to solving this issue is to use the cover glass of the module for heat dissipation. The means for doing this is taught in above-mentioned U.S. patent application Ser. No. 12/957,826 and WO 2011/066286, by several of the same inventors as the present invention.

This approach uses small solar cells and is designed such that the heat dissipation is sufficient for efficient operation. Although glass is not a good thermal conductor it can be used. The key is to spread the heat using small cells, each one of them attached to a small heat spreader, which is attached to the cover glass. The heat spreading capability of cells does not scale with area resulting in the perimeter heat conduction becoming a limiting factor for large cells. Heat production is proportional to the area (length squared), but the perimeter over which heat must flow is only proportional to length. The ratio of the perimeter to the area of a cell decreases as the size of the cell increases so the heat flow rate is inversely proportional to length. This is well known in the CPV industry where at least 2 companies (Soitec http://www.soitec.com/en/products-and-services/solar-cpv/ and Semprius (http://www.semprius.com/) manufacture CPV modules with small cells. The main drawback to using small cells is the increase in the number of manufacturing operations per unit of module aperture area compared to the traditional approach. For this reason, an automatic manufacturing process becomes necessary for small cells. Fortunately, the microelectronics industry has already developed such equipment (pick-and-place equipment, for instance). Some others, such as Semprius, employ micro-transfer printing (http:/ /www.semprius.com/tech_micro-transfer.htm) that is specific to the CPV industry. The use of a flat glass substrate for these automatic processes is common.

U.S. Pat. No. 8,000,018 (by several of the inventors of the present invention) describes HCPV systems using Fresnel-Köhler (FK) architecture. FK designs typically have a better acceptance angle and produce more uniform illumination onto the solar cell than traditional Fresnel-based optical designs.

In above-mentioned US 2010/0126566 there is taught the concept of “sky splitting”, which is a solar photovoltaic system that can efficiently handle both direct and diffuse solar radiation. As some sunlight is diffused by the earth's atmosphere and clouds, not all of the solar radiation can be focused onto the solar cell. The approach is to have two separate types of solar cells, one for high concentration (such as a triple junction cell) and the other to convert diffuse radiation using low cost, low concentration, solar cells. The ratio of the areas of the two cells and their position relative to each other is designed for maximum performance. Also, a portion of the circumsolar radiation not intercepted by the high concentration cells will be handled by the low cost cells, which are the larger in area of the two. This approach is useful in that it can work in a wide variety of climate types, from locations with a high number of sunshine hours per year to those with more cloudy conditions.

In above-mentioned US patent application 2010/0269885, there is taught the concept of “spectral splitting”. In this approach a fraction of the solar spectrum received from the Sun that would have been received by the multi-junction cell is redirected to a second cell, which is a single junction cell. Typically, the wavelengths chosen to be redirected are those which balance the current in the triple junction cell, while producing a combined efficiency of the system which is higher than the multi junction cell itself. A component of a “spectral splitting” system is a special type of spectrally selective filter, which is typically a multi-layer thin film. Various filter designs are possible such as the “L-shape” filters of that patent application as well as band-pass and minus filters. In some filter designs it is useful to divide the energy of certain wavelengths between the multi-junction and single-junction cell, whereas in others sharp cutoff band-pass or minus filters are required. Or the design can be a combination of these two, which is exemplified by the “L” type filter. Also, that application teaches that the incidence angles on the spectral filter ideally should be less than 35 degrees, the lower the better, to reduce the problem of “angle shift”.

A common problem for most CPV architectures is that they have a deep profile. A thin profile is very desirable because there is less material used to make the modules and they require less space for shipping to the site of the power plant. The smaller profile also makes the modules easier to handle. All of these greatly reduce the cost of manufacturing and installation of the system.

Most HCPV systems need careful alignment between the primary optical element (POE) and the secondary optical element (SOE). It would be desirable to have a simple construction that requires little, or no, special alignment between the front of the module and the rear of the module. This lowers the cost of manufacture.

It is, in general, very desirable to have a small SOE. Nevertheless, when the cell is very small, as in the Semprius system, a small SOE may be prohibitive because it is difficult to manufacture and to attach to the solar cell. This can limit the SOEs available in this case to spheres, which can be manufactured with very low cost procedures, but which may not be the most efficient optically and do not provide the other benefits of an SOE.

A problem of small SOEs is that their cost does not necessarily scale with size. Consider an array of devices, each having a PV cell of area A_{c} and a geometrical concentration of C_{g}. Then, each device has an entry aperture area of A_{c}C_{g}, and within one unit of total area there will be 1/(A_{c}C_{g}) concentrator devices. If the cost of one SOE is c_{SOE}, then the total cost of the SOEs contained in one unit of area is c_{SOE}/(A_{c}C_{g}). For small cells, the SOE cost per unit of entry aperture increases dramatically when A_{c} decreases. This is because the cost of placing the SOE is almost constant with size and the cost of manufacturing a glass SOE stays fairly constant even as the amount of material decreases. To help solve this problem, the SOE could be made of injection molded silicone, which for small optics, would have reduced manufacturing costs compared to glass. But, although injected silicone can have lower costs for small sizes, again its cost does not scale, and the cost of placing it remains the same, so this is still not the best solution for very small cells. It would be desirable to lower the cost associated with placement of small cells and their manufacture.

Russian patent 2,496,181 shows a compound optical architecture with a planar mirror that folds the rays of a Fresnel primary back to a PV cell either directly or through a secondary. Several optical architectures are described, with all of them employing a standard circular symmetric Fresnel lens. In FIG. 2 there is no secondary optic, while in FIG. 5 there is simple spherical secondary lens. The secondary lenses of FIGS. 1, 3, and 4 are solid dielectric kaleidoscopes. Also the rear mirror that folds the rays either can be a reflector or a Mangin mirror. (A Mangin mirror is a negative meniscus lens with a reflective surface on the rear side of the glass, forming a curved mirror that reflects light without spherical aberration.) There is no mention of sky splitting or spectral splitting. The embodiment of FIG. 5 (and its related description) of '181 shows a secondary refractive lens 11 that “may be configured . . . as a short-plano lens”. And lens 11 has a spherical cap with gaps between it and primary lens 2. '181 teaches having a secondary optics made of glass, while the separate Fresnel primary is made of silicone. The sides of element 11 are surrounded by air so its walls are reflective. FIG. 2 and FIG. 4 of '181 show Mangin mirrors that require that all of the rays pass through the dielectric mirror and back again, presumably to improve the control of the beam from the primary Fresnel lens onto the secondary. The patent teaches using the front cover to align the primary, secondary and other components. However, there is no guidance on how to control the rotation of the kaleidoscope or other secondary or how to insure the it is in the right X,Y position in a plane that is not on the same plane as the front cover. Also there is no guidance as to how to insure that the primary and secondary lenses are in proper alignment with the PV cell and the heat spreader.

It would be desirable if there was a compound folded concentrating photovoltaic system that addressed some or all of the above limitations of the prior art, and could be easily configured to add sky splitting and spectral splitting apparatus in the factory or in the field.

### SUMMARY OF THE INVENTION

Embodiments of the present disclosure provide a module, especially a high concentration photovoltaic solar power module, referred to as a “Cool Cover Fresnel” or CCF. The optical architecture of the CCF is compound, inasmuch as a portion of the rays in the system are folded by a mirror or spectral filter located near the rear of the module and redirected toward the front of the module. This approach reduces the depth of the module by approximately half, compared with a module in which a Fresnel POE at the front of the module focuses the light directly onto an SOE and PV cell at the back of the module. The position of a multi-junction cell is inside the front cover just below a heat spreader, which is attached to the front cover. Surrounding the multi-junction cell is a solid dielectric secondary lens, which in the preferred embodiments has four-fold symmetry to work in conjunction with a four-fold primary Fresnel lens, as taught in U.S. Pat. No. 8,000,018, to achieve Köhler integration of solar radiation onto a front-located multi-junction cell. The mounting position of SOE and multi junction cell components is similar to what is taught in U.S. Ser. No. 12/957,826 and WO 2011/066286, an important difference being that in the present modules, the POE is also a lens attached to the front cover, not a mirror at the rear of the module. The basic construction of the POE is a method known as “silicone-on-glass” (SOG). With this method the Fresnel lens can made of silicone that is constructed by various means onto a sheet of glass. The use of a glass outer surface has advantages, as it protects the other components in areas of high moisture and areas of wind-blown sand. And the SOE and POE are molded at the same time as one piece.

In one embodiment, a high concentration photovoltaic device comprises a Fresnel lens having a front side and a back side, a mirror behind the Fresnel lens and facing the Fresnel lens, a secondary lens unitary with the Fresnel lens and facing the mirror, and a photovoltaic cell in front of the secondary lens and facing the mirror through the secondary lens. Two optical elements of the device form a Köhler integrator between a remote source in front of the Fresnel lens and the photovoltaic cell as a target.

The unitary Fresnel lens and secondary lens may be formed on the back of a cover plate. The cover plate may then be glass, and the unitary Fresnel lens and secondary lens may be of plastic molded onto the cover plate. The photovoltaic cell may then be embedded in the plastic between the secondary lens and the cover plate.

The device may further comprise a heat spreader between the photovoltaic cell and the cover plate, in thermal contact with the photovoltaic cell and the cover plate.

The heat spreader may further comprise arms radiating from the photovoltaic cell, the arms being in contact with a back side of the cover plate along the length of the arms.

6. The device may further comprise a second heat spreader on a front side of the cover plate, the second heat spreader having arms in contact with the back side of the cover plate along the length of the arms, the arms of the second heat spreader being aligned in front of the arms of the first heat spreader and the second heat spreader being separated from the first heat spreader by the cover plate, so that at least some of the heat from the first heat spreader is conducted to the second heat spreader through the cover plate, is conducted radially outwards on the front side of the cover plate by the arms of the second heat spreader, and is returned to the cover plate by the second heat spreader for dissipation into the external environment.

The device may further comprise a third lens in front of the mirror. Any two of the Fresnel lens, the secondary lens, and the third lens may then form the Köhler integrator.

The mirror may be mounted tiltably relative to the Fresnel lens.

The mirror may be a frequency selective partially transmissive mirror, and the device may then further comprise a second photovoltaic cell behind the mirror. The photovoltaic cell in front of the secondary lens may then be a multi-junction photovoltaic cell, and the second photovoltaic cell may then be a single-junction photovoltaic cell.

The frequency selective partially transmissive mirror may be a band-pass mirror comprising a long-pass mirror and a short-pass mirror, which may be formed one on each side of a sheet of glass or other substrate.

The long-pass mirror may be partially transmissive at wavelengths longer than the pass-band of the band-pass mirror, and/or the short-pass mirror may be partially transmissive at wavelengths shorter than the pass-band of the band-pass mirror, and the two mirrors may then be matched so that at least some wavelengths outside the pass-band at which each mirror is partially transmissive are wavelengths at which the other mirror is substantially completely reflective.

The mirror may be smaller in area than the Fresnel lens, and the device may then further comprise an additional photovoltaic cell behind an outer part of the Fresnel lens outside the mirror, operative in use to generate electricity from light incident from directions other than directly in front of the Fresnel lens.

The CCF embodiments taught herein employ Köhler integration while some add additional “spectrum splitting” and/or “sky splitting” functionality. However, other possible optical architectures can used as well and will be evident to those skilled in the art once the principles taught herein are fully understood.

A “Köhler integrator” is a device in which a first optical element images a light source onto a second optical element, and the second optical element images the first optical element onto a target. In one ideal configuration, not usually achievable, the image of the source exactly coincides in shape, size, and position with the second optical element, and the image of the first optical element exactly coincides in shape, size, and position with the target. In a solar photovoltaic module, the “source” is typically either the sun, or a disk defined by the “acceptance angle” of the module, centered on the sun and including an allowance for tracking errors, as discussed above. The “target” is then typically the active entry surface of the actual photovoltaic cell. However, in some embodiments with more complex optics, either the “source” or the “target” may be an intermediate image at which the light is transferred from or to another optical element. Either or both of the optical elements of the Köhler integrator may be, for example, a mirror, a lens, or one refractive surface of a thick lens or other transparent body. The Köhler integrator may include additional “relay” or “intermediate” optical elements between the first and second optical elements that form the actual Köhler integrator.

Because most HCPV systems have a separate POE and SOE, each of these also need separate holding fixtures. In some cases a number of POEs are manufactured into a single panel, and this does help. It is highly beneficial to combine the POE and SOE into a single panel and have the POE and SOE fabricated at the same time, making additional alignment unnecessary. This improves the performance of the system and also reduces manufacturing costs. This is particularly important when the cells are small, because in this case in the prior art approach, the number of concentrators per unit of entry aperture area is high and since all the manufacturing operations are proportional to the number of concentrators, the number of parts becomes a huge problem. By having the secondary and primary lenses manufactured as one piece this mitigates the problem of the prior art.

The SOE in the present devices also facilitates cell electrical and moisture isolation. It is desirable that the SOE completely encapsulate the solar cell and the electrical connection to the solar cell. And when the solar cell is behind a plate of glass, the entire electrical system can then be well protected. This approach is also advantageous because the cell encapsulation can be handled at the same time as the molding of the one-piece Fresnel lens POE and SOE. This has a big advantage over the prior art.

In a first embodiment, which does not employ “spectrum splitting” and “sky splitting”, there is a front cover made of glass and components proximate to it comprising: a heat spreader (and related components as taught in U.S. Ser. No. 12/957,826 and WO 2011/066286), a multi junction cell (and related electrical components) and a four-fold secondary refractive lens molded as one with a four-fold primary lens. To the rear of the module in this embodiment there is a centrally located mirror on a substrate, which folds rays from the primary lens to the secondary refractive lens. The mirror needs to cover only a central area of the substrate, about half the width of the primary lens.

In a second embodiment, sky splitting apparatus are added to the first embodiment by adding PV cells onto the region of the substrate which is not covered by the mirror. In a third embodiment, spectral splitting apparatus are added to the first embodiment by replacing its centrally located mirror with a single-junction PV cell covered by a spectral selective filter. The latter element sends one fraction of the radiation received from the primary lens to the single-junction PV cell below it (by transmission) and the remaining fraction to the refractive secondary lens above it (by reflection). In a fourth embodiment, both sky splitting and spectrum splitting apparatus are added to the first embodiment by replacing its mirror with the sky the splitting apparatus of embodiment 2 and the spectral splitting apparatus of embodiment 3.

In a fifth embodiment, a tracking adjustment function is added to any of the previous embodiments by allowing the mirror to have an adjustable tilt. In a sixth embodiment there is added to the first embodiment, a secondary Fresnel lens in front of the mirror.

An optional spherical glass ball can be molded into a region of the secondary for all the above embodiments to improve transmission compared to an all silicone secondary. This can be achieved using standard molding techniques so that the ball (manufactured in volume) is placed as an insert in the mold in position with respect to the refractive lens and primary features and the silicone will fill the gaps in between the ball and the secondary cavity.

There are many advantages for CCF. What follows is a short list of some of them for embodiments without sky splitting and spectrum splitting. Those familiar in the art will know of other advantages.

1) With the small SOE used in the CCF, the SOE and POE are both manufactured with the SOG process at the same time. By molding them together the SOE costs very little extra. In the prior art the POE and SOE are made separately, increasing the cost of manufacture.

2) As the POE and SOE are molded at the same time they almost perfectly aligned. This overcomes a major issue of the prior art, as it difficult to line up accurately a POE and SOE, which in many cases are not even mounted on the same plane, so they have many degrees more of freedom to be out of alignment (X,Y,Z and rotational).

3) Because the POE and SOE are made of the same material and located on the same surface, the system avoids the mismatch in the coefficients of thermal expansion (CTE) that can affect other systems.

4) The SOE and POE alignment depends only on the parallelism of the glass substrate of the POE and the mirror.

5) The cell and heat spreader can be placed on the glass substrate using a very economical “pick-and-place” method.

6) As the cell is small, the heat spreader can also be small, and still have enough heat transfer to the glass to keep cell temperature within its desirable temperature range. In fact the heat spreader size can in many cases be limited to the projected area of the SOE, so that it does not cause any additional loss of useful light collection area.

7) The invention allows the module to be vertically very compact, about half the height of other HCPV systems with a similar cell size and concentration.

There are also advantages of the basic CCF configuration when used in conjunction with sky splitting and spectrum splitting features of this disclosure. A partial list follows:

1) The spectrally selective reflector is planar and can be designed to operate with air on one side and a solid dielectric on the other or with both sides in air. Those with both sides in air can be easily replaced with new ones in the field. It occupies only about ¼ of the POE area, which implies a cost advantage with respect to systems which use a selective reflector of larger area, and operates only at about 4x concentration, which implies low risk of degradation.

2) The angles of incidence of the ray bundle from the POE onto the spectrally selective reflector are typically all less than or equal to 25 degrees. The angle is determined by the f-number of the Fresnel POE, which is limited by other considerations. The prior art spectrum-splitting HCPV systems of other designs typically have angles of incidence on the spectrally selective element of 35 to 45 degrees or even much higher, which are much more difficult to design and manufacture.

3) A hybrid CCF system with sky and spectral splitting is easy to implement in the present devices, because the lower-concentration photovoltaic cells for both apparatus can reside on the same plane, and are in a sub-assembly separate from the primary and secondary lenses and the high-concentration PV cell. This allows for optimization of systems for a wide variety of climates as different type of cells can be easily swapped for others to match the climate conditions and design goals.

4) The hybrid CCF systems will be able to achieve higher efficiencies compared to prior art designs based on solar concentration systems using only multi junction cells. First, a properly designed CCF with a high efficiency multi-junction cell and added spectrum splitting hardware (cell and spectrally selective reflector) can achieve a higher efficiency than one without this hardware for sunny climates (on the order of a 10% increase). The additional sky splitting functionality will further boost the performance for a wide variety of climate types compared to prior art solar concentrator PV systems, broadening the systems' commercial viability.

Other embodiments also provide the mentioned heat spreaders and/or frequency selective filters independently of the other mentioned novel features, in other forms of photovoltaic concentrator or elsewhere.

### BRIEF DESCRIPTION OF THE DRAWINGS

The above and other aspects, features and advantages of the present invention will be apparent from the following more particular description thereof, presented in conjunction with the following drawings wherein:

FIG. 1A shows the location of an SOE in relation to a primary Fresnel lens of the prior art with exemplary mirror horizontal axis.

FIG. 1B shows derivation of a CCF embodiment from the device of FIG. 1A.

FIG. 2 shows a cross-sectional view of a CCF embodiment with a folding mirror and exemplary rays.

FIG. 3 shows a cross-sectional view of a CCF embodiment with a sky splitting apparatus.

FIG. 4 shows a cross-sectional view of a CCF embodiment with spectral splitting apparatus.

FIG. 5 shows a cross-sectional view of a CCF embodiment with a simplified sky splitting and spectral splitting apparatus.

FIG. 6 shows a cross-sectional view of a CCF embodiment with a reflector which has an adjustable tilt.

FIG. 7 shows a cross-sectional view of a CCF embodiment with a secondary Fresnel lens.

FIG. 8A shows a plan view of a parent four-fold Köhler Fresnel lens before being merged with a secondary lens.

FIG. 8B show a plan view of the Fresnel lens of FIG. 8A merged with an SOE.

FIG. 8C shows a CCF embodiment with a displaced four-fold Köhler Fresnel lens.

FIGS. 9A, 9B, and 9C show a CCF with a sky splitting and spectral splitting apparatus.

FIG. 10 shows an optional spherical ball molded into the secondary lens of a CCF.

FIG. 11A shows the spectral transmittance of an exemplary band-pass filter, for several angles of incidence suitable for a CCF embodiment employing spectral splitting.

FIG. 11B is a spectral transmittance plot of a modified longpass filter.

FIG. 11C is a spectral transmittance plot of a modified shortpass filter.

FIGS. 12A, 12B, 12C, 12D, 12E and 12F shows a number of Primary/Secondary optical architectures of the prior art.

FIG. 13 is a perspective view from above of part of a further CCF embodiment.

FIG. 14 is an exploded view from below of the embodiment of FIG. 13.

FIG. 15 is a somewhat schematic plan view of an array of devices according to FIG. 13.

### DETAILED DESCRIPTION OF THE PREFERRED EMBODIMENTS

A better understanding of various features and advantages of the present invention will be obtained by reference to the following detailed description and accompanying drawings, which set forth illustrative embodiments in which certain principles of the invention are utilized.

Reference is now made to FIG. 1A which shows prior art Fresnel Köhler PV Concentrator 100 of U.S. Pat. No. 8,000,018, comprising Heat Spreader 104, Multi-junction Cell 105, Four-fold Fresnel Köhler secondary refractive lens 106, Four-fold Fresnel Köhler primary refractive lens 109, Front Cover 110, exemplary rays 107 and 108. Also there is horizontal Imaginary Plane 112 at a vertical height halfway between top and bottom. Imaginary Plane 112 is represented by two horizontal dotted lines. Exemplary ray 107 originates from the edge of lens 109 while ray 108 originates from near the center of lens 109.

FIG. 1B illustrates the derivation of an embodiment of the present cool cover Fresnel (CCF) concentrator from that of FIG. 1A. All elements that in concentrator 100 were below Imaginary Plane 112 are mirrored above Imaginary Plane 112 such that a CCF 120 is derived. CCF 120 is a compound optical system comprising mirror 113, which is in the same position as Imaginary Plane 112, Heat Spreader 104a, Multi-junction Cell 105a, Four-fold Fresnel Köhler Secondary Refractive lens 106a, Four-fold Fresnel Köhler primary refractive lens 109a, Front Cover 110, exemplary rays 107a, 107b and 108a. Heat spreader 104a is attached to Front Cover 110 with Cell 105a attached to it. Surrounding Heat Spreader 104a and Multi junction Cell 105a is Secondary refractive lens 106a, which hermitically seals Heat Spreader 104a and Multi-junction Cell 105a. Primary Lens 109a covers the remaining surface of Front Cover 110. Primary Lens 109a and Secondary Lens 106a flow into each other, forming a continuous solid dielectric component with no air gaps. Ray 107a is the part of ray 107 which is above the top of reflection plane 112, while ray 107b is derived from the lower part of ray 107 by reflection in mirror 113 at plane 112. Also folded upward are elements 104, 105, 106 to form 104a, 105a and 106a. Ray 108a is only imaginary, because the central rays such as 108 no longer exist in the folded optics, because they are blocked by Heat Spreader 104a.

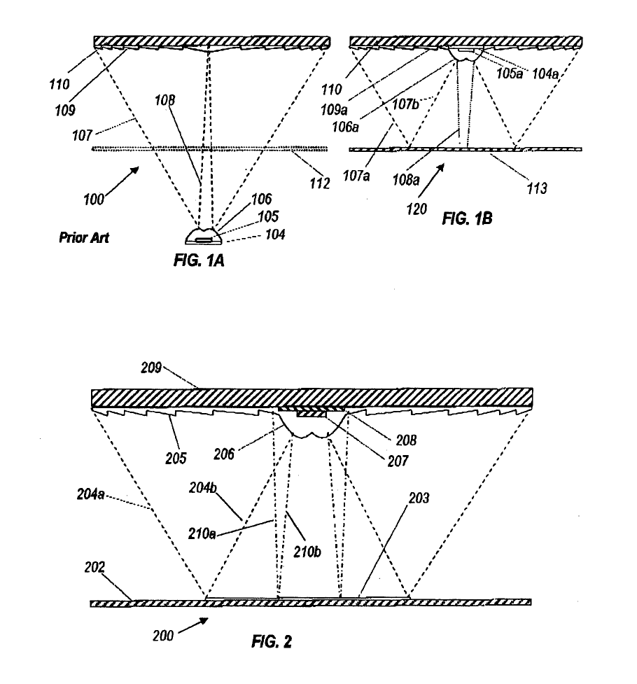

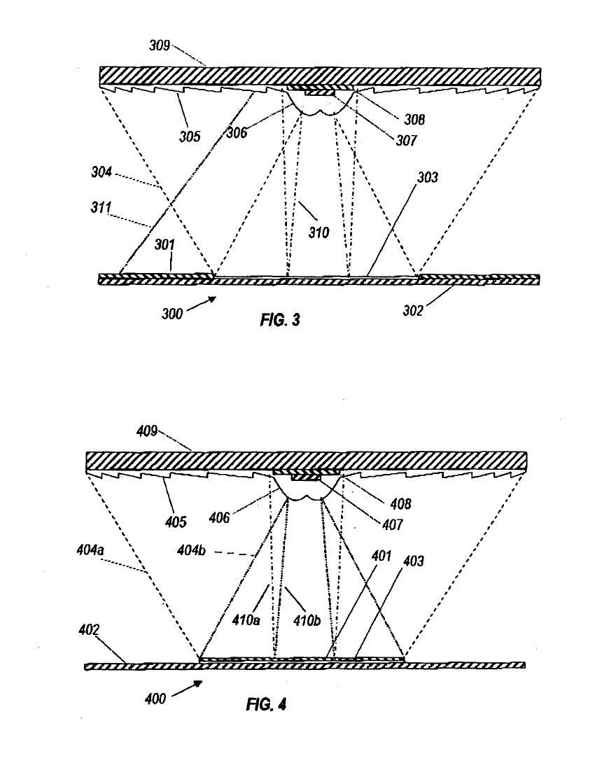

FIG. 2 shows CCF 200 which is a more detailed cross-section view of an embodiment similar to that of FIG. 1B, comprising Substrate 202, Mirror 203, Heat Spreader 208, Multi junction Cell 207, Four-fold Fresnel Köhler secondary refractive lens 206, Four-fold Fresnel Köhler primary refractive lens 205, Front Cover 209, with exemplary rays 204a, 204b, 210a and 210b. Similar components of embodiment CCF 200 to those of CCF 120 behave the same, the only new element being Mirror 203, which covers substrate 202. It is important in this embodiment to distinguish the substrate from mirror, as it is unnecessary in CCF 200 to mirror the entire surface of Substrate 202. It will be seen that this distinction is needed for other CCF embodiments as well. Exemplary rays 204a and correspond to rays 107a and 107b of CCF 120. However, rays 210a and 210b are not the same as dotted ray 108a. Ray 210a originates from the inner part of Primary lens 205, just outside the area blocked by secondary lens 206 and heat spreader 208, and Ray 210b is the reflection of Ray 210a off Mirror 203. Note that Rays 204b and 210b intersect one point on the surface of secondary Lens 206. This is a requirement of a Fresnel Köhler Concentrator, assuming that the rays 204a, 210a are refracted at primary lens 205 from parallel incident rays, originating at a single point of the sun (not shown). And ideally all the rays originating from Lens 205 between 204a and 210a by refraction of the same parallel beam should meet this requirement.

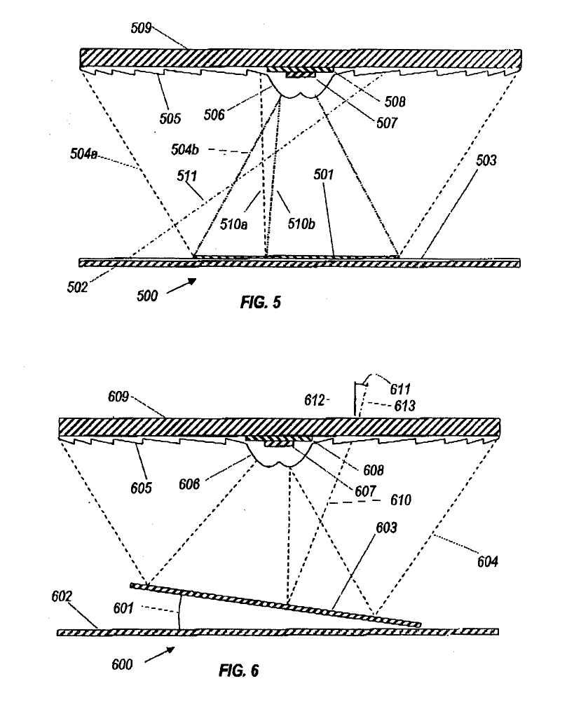

FIG. 3 shows CCF 300 with similar elements to CCF 200 but with an additional sky splitting PV cell or cells 301 on Substrate 302. Mirror 303, Heat Spreader 308, Multi-junction Cell 307, Four-fold Fresnel Köhler secondary refractive lens 306, Four-fold Fresnel Köhler Primary Refractive Lens 305, and Front Cover 309, with exemplary rays 304, 310 and 311, are generally similar to the corresponding features of FIG. 2, and their description will not be unnecessarily repeated. The only difference between this embodiment and that of FIG. 2 is that the sky splitting PV cells 301 surround the mirror 303 such that rays missing the mirror will be intercepted by Cells 301 and be converted to electricity. Typically, Cells 301 are lower cost cells than the multi junction cell. This is illustrated by Exemplary Rays 304, 310 and 311. Exemplary Rays 304 and 310 are redirected by Mirror 303 and focused at the surface of secondary Lens 306 as in FIG. 2, but Exemplary Ray 311 misses Mirror 303 and is intercepted by PV Cells 301. The incident ray that is refracted to form exemplary ray 311 does not come from the same part of the sky as the parallel beam of sunlight that is refracted into exemplary rays 304, 310. The advantage of this approach is that the system will handle both direct, diffuse and circum-solar radiation from the Sun and the sky. Even under sunny conditions there is still a considerable amount of radiation that is coming from regions of the sky outside the Sun. And when there is little or no direct radiation from the sun, the system can still generate electricity using diffuse light from the sky.

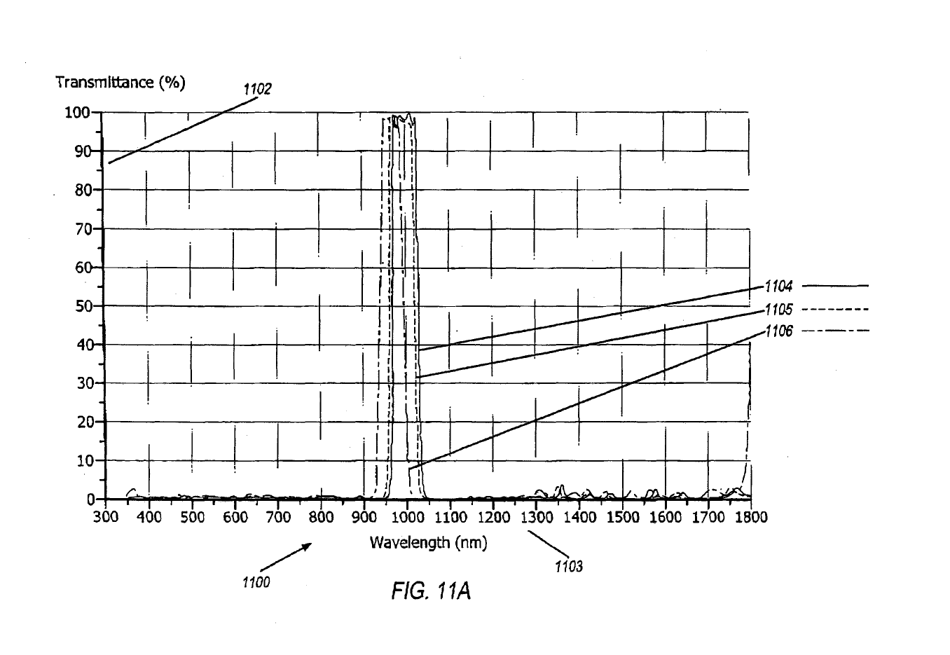

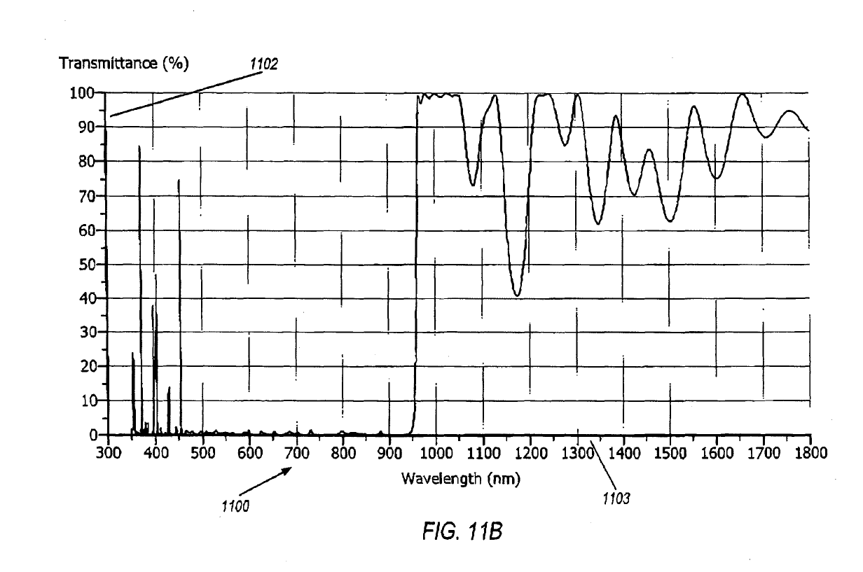

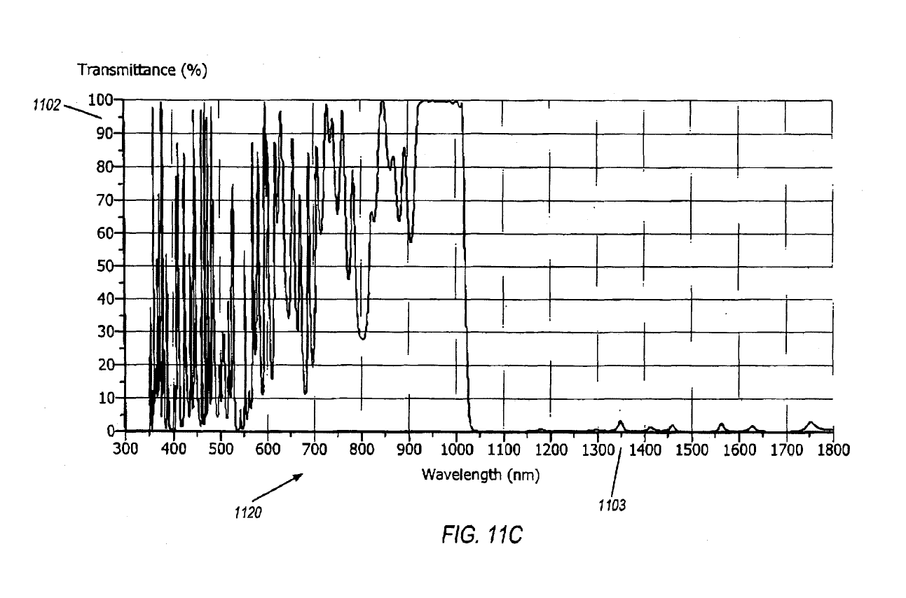

The solar cells used for HCPV cannot convert the entire solar spectrum into electricity. With present day “multi-junction” (MJ) cells some of the spectrum is under-utilized. By adding a single junction solar cell that is designed for this unused spectrum, more of the solar spectrum can be converted to electricity. FIG. 4 shows embodiment CCF 400 that utilizes “spectrum splitting”. CCF 400 is comprised of Substrate 402, Dichroic Mirror 403, Single Junction Cell 401, Heat Spreader 408, Multi-junction Cell 407, Four-fold Fresnel Köhler secondary refractive lens 406, Four-fold Fresnel Köhler Primary Refractive Lens 405, Front Cover 409, with exemplary Rays Dashed 404a, Dotted 404b, Dashed 410a, Dotted 410b. Dichroic Mirror 403 reflects the spectrums used by Multi-junction Cell 407 and allows transmission of the spectrum used by Single Junction Cell 401 (a preferred cell is Si cell), which is specifically designed for the spectrum not fully utilized by the MJ cell. The Dotted Ray 404b is the component reflected from Dichroic Mirror 403 of Exemplary Ray Dashed 404a, which originates from the edge of Primary 405. Similarly, Dotted Ray 410b is the reflected component of Dashed Ray 410a. In a preferred embodiment Dichroic Mirror 403 is designed to be a band-pass filter. Details of a suitable filter for use with a system with a triple-junction cell and Si cell are provided in FIGS. 11A, 11B and 11C and their description.

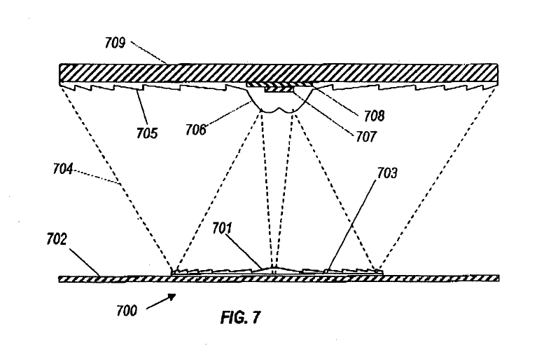

FIG. 5 shows embodiment CCF 500 with Dichroic Filter 501 that is approximately ¼ the area of the aperture area of the entrance aperture of the device and which partially covers a low cost PV cell 503. CCF 500 is comprised of Substrate 502, Dichroic Mirror 501, Single Junction Cell 503, Heat Spreader 508, Multi junction Cell 507, Four-fold Fresnel Köhler secondary refractive lens 506, Four-fold Fresnel Köhler Primary Refractive Lens 505, Front Cover 509, with exemplary Rays Dashed 504a, Dotted 504b, Dashed 510a, Dotted 510b, dot dashed 511. CCF 500 utilizes a simplified approach to combining spectral and sky splitting. Exemplary Rays 504a, 504b, 510a and 510b perform similarly to Rays 404a, 404b, 410a and 410b of FIG. 4. Dot Dashed Ray 511 performs similarly to Ray 311 of FIG. 3. The single junction cell 503 covers the substrate 502 over an area corresponding to the whole area within the periphery of primary lens 505, and possibly also including any gap between primary lens 505 and the neighboring modules. The part of single junction cell 503 under mirror 501 acts as the secondary cell of a spectrum splitter, similarly to cell 401. The outer part of single junction cell 503 acts as the secondary cell of a sky splitter, similarly to cell 301. Single junction cell 503 may be a mosaic of smaller cells.

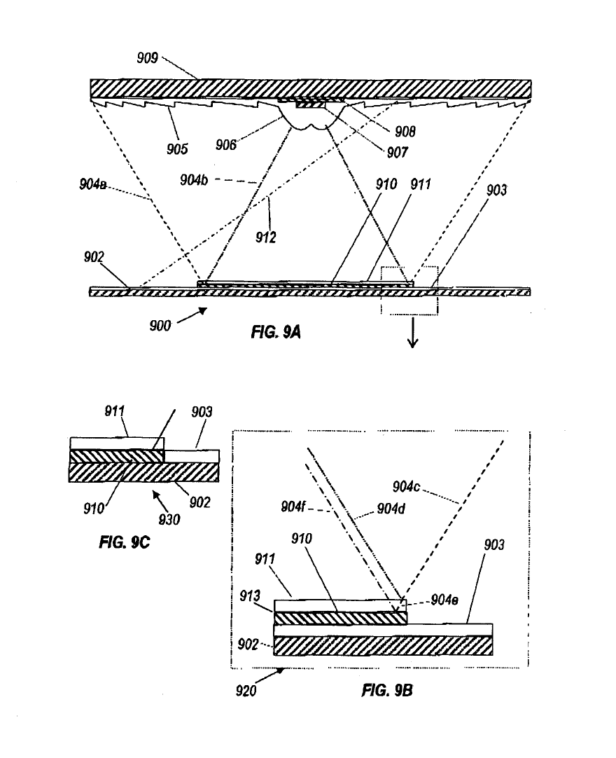

The CCF architecture is much simpler than some of the earlier approaches taught in the aforementioned inventors' previous applications. The new approach can easily handle both sky splitting and spectrum splitting in the same module, as exemplified by the embodiments of FIG. 5 and FIG. 9.

FIG. 6 shows a configuration with a tilting mirror 603 that provides a limited tracking of the sun. Incoming light 613 is tilted by an angle 611 to the normal 612 to flat cover 609. This off-axis light is still redirected to the solar cell 607 by means of a rotation of mirror 603. Also each concentrator flat mirror can be tilted to provide fine-tuned tracking. The mirror, as well as its tracking mechanism is inside the concentrator module housing, so the module has an “effective acceptance angle” bigger than the one provided by just the optics. This fine tracking could have a range angle of several a, where a is the acceptance angle. In this way the “effective CAP” could be increased so low accuracy trackers (like the ones used for non-concentrating modules) could be used for HCPV, which would offset the extra cost of the movable mirrors.

The rotation movement can be centered near the center of the mirror. The rotation center could also be more than a single point so that both rotation and displacement movements are combined to compensate for off-axis focal length variations. The movement could also be only a displacement parallel to the optical axis of the system that compensates focal length variations of the optical system.

FIG. 7 shows a configuration in which primary Fresnel lens 705 redirects sunlight onto a (virtual) area below Fresnel lens 701. Lens 701 further concentrates this light onto SOE 706. This is accomplished by having lens 701 increase the angle 711 of the light reaching the SOE 706 when compared to angle 710 that lens 705 produces. The additional cost can be justified in high concentration cases where a higher CAP becomes a must. This additional 2^{nd} lens can be used to increase the illumination angle of the cell (thereby increasing the CAP), and/or to correct the chromatic performance of the concentrator (i.e. decrease chromatic aberrations). This second lens can be stepped, like the Fresnel shown in FIG. 7, or a continuous lens. Note that due to the flat mirror, this lens will behave as a double curved surface lens for the reflected rays, and a small lens curvature will create enough optical power. The effect of the lens on light collected by the secondary photovoltaic cell 401, 503, 910 is not usually significant, but the spectrum splitting mirror may need to be recalculated because the range of incidence angles on it is changed by the lens.

With the conventional FK system, the POE and SOE form the two-element Köhler lens pair. With the addition of the “2^{nd} lens”, the Köhler lens “pair” can be any combination of the three lenses. In FIG. 7 it is the original POE and SOE, the 1^{st} and 3^{rd} lenses respectively. For example, the “pair” could also be the 1^{st} and 2^{nd} lenses.

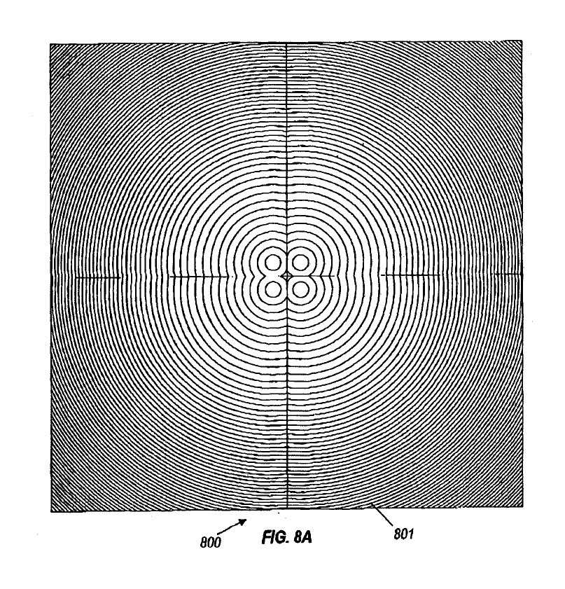

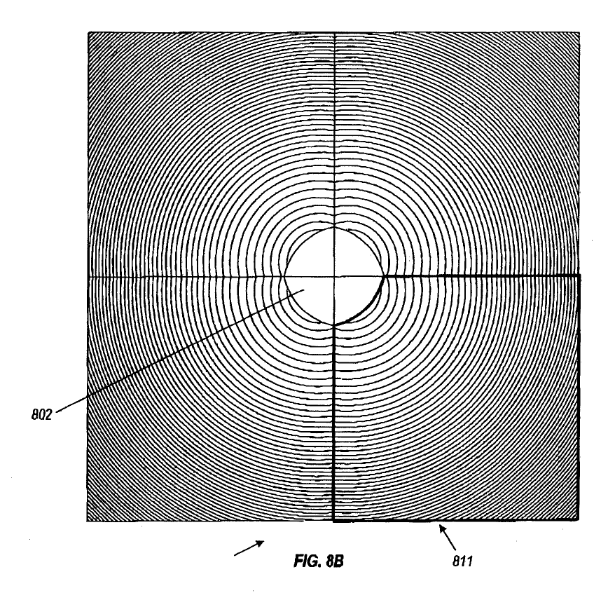

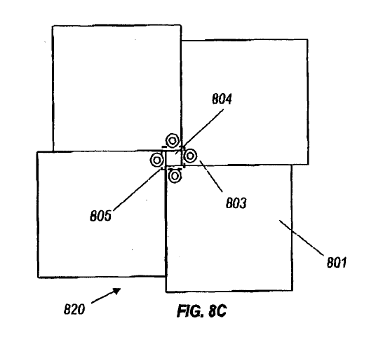

FIG. 8A shows a plan view of Fresnel Köhler Primary Optical Element 800 of the prior art. Element 800 has four separate sections, each one obtained as an off-axis square of a rotational Fresnel lens. FIG. 8B shows a plan view of Element 800 of FIG. 8A merged with Secondary lens 802 to form unified POE/SOE 810 suitable for molding as one piece, as required by embodiments taught herein. This arrangement, however, results in four symmetric POE quadrants that are not fully square. Part of the center corner of each POE quadrant is removed by the SOE, resulting in a POE whose shape is as indicated by outline 810. This shape 810 is then imaged onto the solar cell by the corresponding quadrant of the SOE. This results in an irradiance pattern on the solar cell whose corners are not well illuminated. One way to overcome this limitation is with POE 820 arranged as shown in FIG. 8C. Here, instead of the four quadrants in FIG. 8A being trimmed at the center by the SOE, they are displaced around a central square 804. Now each POE quadrant 801 retains its square shape, and each corresponding section of the secondary will image it onto the solar cell, producing there a uniform, square irradiance pattern. Area 804 is reserved for the heat spreader and the SOE. Area 804 is square, and is correctly aligned with POE quadrants 801. This configuration may be arrayed so that several of these can be placed side by side.

In FIG. 9 there is a hybrid system that uses an alternative spectrum splitting architecture to that of FIG. 5 while also utilizing diffuse radiation from the sky. In this apparatus the dichroic filter 911 covers a high efficiency Si cell 910, such as the BPC cells made by Sunpower, and there is also a low cost cell 903 that surrounds the high efficiency cell 910, whose perimeter encompasses the same area as the entrance aperture of the device. In this system the Si high efficiency cell is approximately ¼ the area of the entrance aperture and the low cost PV cell is approximately ¾ of that area. FIG. 9, consisting of FIGS. 9A, 9B and 9C, shows CCF 900 with spectral and sky splitting apparatus comprising Substrate 902, Dichroic Mirror 911, Single Junction Cell 903, High Efficiency Single Junction Cell 910, Heat Spreader 908, Multi-junction Cell 907, Four-fold Fresnel Köhler secondary refractive lens 906, Four-fold Fresnel Köhler Primary Refractive Lens 905, Front Cover 909, with exemplary Rays Dashed 904a, Dotted 904b, Dashed 904c, Dotted 904d, Long Dashed 904e, Dot Dashed 904f and Dot Dashed 912. Exemplary Rays 904a and 904b perform similarly to Rays 404a, 404b of FIG. 4. Dot Dashed Ray 912 performs similarly to Ray 311 of FIG. 3.

FIG. 9B is a detail of a corner of FIG. 9A and shows what happens to Dashed Ray 904C when it intercepts the first surface of Dichroic Mirror 911. A fraction of the ray's energy is reflected by the front face of Mirror 911 and shown as Dotted Ray 904d. The transmitted component is Long Dash Ray 904e. A fraction of Ray 904e is reflected by the rear surface of Dichroic Mirror 911, a fraction of which exits the front face of Mirror 911 as ray 904f. A fraction of ray 904e is absorbed by High Efficiency Cell 910. Only a few of the primary rays are shown but others would propagate inside and out of the solid dielectric dichroic mirror. Dichroic Mirror 911 will have an air interface on its top surface. However, there are two options for its bottom surface, one with an air interface to an air gap between dichroic mirror 911 and high efficiency cell 910 and the other with a solid dielectric interface such as an adhesive to high efficiency cell 910.

FIGS. 9A and 9B show High Efficiency Cell 910 on top of Cell 903. That is a simple configuration to produce, because the fabrication of layers 902 and 910 is independent. However, in a more preferred configuration, as shown in FIG. 9C, Cell 910 is attached to substrate 902 on the same plane as Cell 903 within an aperture in Cell 903. The latter configuration is more compact, and more economical of material.

Mirror 911 can either be a one or two-sided dichroic mirror. In FIG. 11 there is Transmittance Plot 1100 for a two-sided dichroic mirror, with a front face that is the longpass filter of Table 1 and a back face that is the short-pass filter of Table 2. This filter is suitable for implementing spectrum splitting for the embodiments of this disclosure. The transmission regions of modified longpass and shortpass stacks (by modified this means they are not traditional longpass or shortpass stacks but have regions which meet this requirement) overlap each other such that a square shaped band-pass region is created with near 100% transmittance, while outside this region there is over 99% reflectance. Transmission Plot 1110 of the modified longpass filter at an incidence angle of 12.5° is shown in FIG. 11B. Transmission Plot 1120 of the modified shortpass filter at an incidence angle of 12.5° is shown in FIG. 11C. The reflected radiation spectral characteristics are chosen to balance the currents of a typical triple-junction cell. Both sides of this filter interface with air. The order of Table 1 starts from the air layer and then to the substrate. In the manufacturing process the first layer to be coated is layer 82. This same is true for the coating order for Table 2, as layer 55 would be the first one to be deposited on the back side of the substrate, which in this case is a 1 mm thick BK7 glass. Note that both these filters are two material design using alternating layers of SiO2 and Ta2O5.

The method of designing the longpass filter of Table 1 can be summarized as follows. You start with the following seed formula: 0.73 (.75H.5L.75H)̂8 0.85(.75H.5L.75H)̂8 1.0(.75H.5L.75H)̂8 1.18(.75H.5L.75H)̂8 1.30(.75H.5L.75H)̂8, where H represents a quarter wave thickness of the high index material, in this case Tantalum Pentoxide, and the L represents a quarter wave thickness of the low index material, in this case Silicon Dioxide. The convention is that the stack is defined as from the medium (air) to the substrate (BK7 glass). The constants in the seed formula, 0.73, 0.85, 1.0, 1.18 and 1.30 can be modified as needed as can the number of terms of the (.75H.5L.75H)̂8. For example, the term with the constant 0.73 creates a high reflectance region centered at approximately 425 nm with a width of 100 nm and region of high transmittance at longer wavelengths. The next term with the constant 0.85 adds a reflectance zone centered at approximately 525 nm with a 100 nm width and region of high transmittance at longer wavelengths but with ripples going from approximately 50 to 90% transmittance below 475 nm, which is in reflectance zone relating to the 0.73 term. This lower rippled zone reinforces the reflection of the 0.73 term stack. By adjusting the constants for a number of (.75H.5L.75)̂8 terms an excellent starting long pass filter can be designed. Then one must set up the desired targets and apply optimization to reach the final design.

The targets are based on the desired 100% transmission zone, which in this case is 964 nm to 1028 nm, and the shorter wavelength region, where a 100% reflectance is desired, which in this case is 350 nm to 962 nm. Note that the targets are in 2 nm increments going from 350 nm to 1028 nm. No targets are set above 1028 nm, allowing the zone above 1028 nm to 1800 nm to have transmission ripples with spikes and troughs, which is this case may be desirable, as will be explained below. A target of 100% reflectance with a tolerance of 0.05 is set for the shorter wave band and a target of 100% transmission with a tolerance of 0.05 is set for the transmission band. The reference angle is set to 642 nm and the angle of incidence for all wavelengths is set to the mean wavelength of the bundle of rays striking the two-sided filter, which in this case is 12.5°. Also setting minimum and maximum thickness for each element in the stack is useful to make sure the stack is manufacturable. For the design in Table 2 a minimum of 20 nm and maximum of 200 nm for all layers in the stack. Optimization using standard Simplex or Conjugate Gradient or others known in the prior art arrive readily to the solution.

The method of designing the shortpass filter uses the more standard starting seed formula of (LH)̂27L, where H and L are the same two materials in the longpass stack. In this case the zone of 100% transmission is set substantially the same as the longpass filter, while the 100% reflectance zone is set to start a few nm above the end of the transmission zone and end at the longest wavelength of the design, in this case 1800 nm. The tolerance settings for the transmission and reflectance zones are 0.1. And the angle of incidence for all the targets is chosen to be the median of the bundle of rays on the filter, which as before is 12.5° . In this case the lower reflectance band starting from 350 nm is allowed to float. The optimization approaches of refinement and synthesis can be used to closely meet the target goals. In this case for the design of Table 2 the approach used was the Optimac algorithm in the software Essential Macleod by The Thin Film Center, Inc of Arizona, USA.

After the long pass and short pass designs are completed, the two can be modeled as a complete two-sided filter on a substrate. The stacks can be further refined using optimization techniques with the targets now including the full range of wavelengths, which in this case are from 350 nm to 1800 nm. Typically, this is not required. However, another approach can be used which works quite well and is very easy to implement. The approach is to make small adjustments in the reference angle so that either the shortpass or longpass filters are either moved to the left on the transmission plot (toward the shorter wavelengths) or to the right (toward the longer wavelengths). If the transmission zones for the shortpass and longpass filters are a little wider than is required, this allows for adjustment of the two positions of the curves using the reference angle. And also it allows the designer to pick the zones of desired reflectance such that undesirable spikes in one of the filters in the reflectance zone lines up with a trough in the other in the same wavelength region. This works very well for the short wavelength region of the longpass filter where the spikes are very narrow in width but not so well for the longer wavelength. Still, even in the longer wavelength region there is a reflectance boost resulting from the multiplicative effect of having two filters.

TABLE 1
Design: Longpass - Front side
Reference Wavelength (nm): 642

| | | | | | Optical | Physical | |
|---|---|---|---|---|---|---|---|
| | | Packing | Refractive | Extinction | Thickness | Thickness | Geometric |
| Layer | Material | Density | Index | Coefficient | (FWOT) | (nm) | Thickness |
| Medium | Air | | 1 | 0 | | | |
| 1 | Ta2O5 | 1 | 2.13255 | 0 | 0.158404 | 47.69 | 0.074279 |
| 2 | SiO2 | 1 | 1.45677 | 0 | 0.172702 | 76.11 | 0.118552 |
| 3 | Ta2O5 | 1 | 2.13255 | 0 | 0.172362 | 51.89 | 0.080825 |
| 4 | SiO2 | 1 | 1.45677 | 0 | 0.157011 | 69.2 | 0.10778 |
| 5 | Ta2O5 | 1 | 2.13255 | 0 | 0.163053 | 49.09 | 0.076459 |
| 6 | SiO2 | 1 | 1.45677 | 0 | 0.193165 | 85.13 | 0.132598 |
| 7 | Ta2O5 | 1 | 2.13255 | 0 | 0.178758 | 53.81 | 0.083824 |
| 8 | SiO2 | 1 | 1.45677 | 0 | 0.192102 | 84.66 | 0.131869 |
| 9 | Ta2O5 | 1 | 2.13255 | 0 | 0.254571 | 76.64 | 0.119374 |
| 10 | SiO2 | 1 | 1.45677 | 0 | 0.197447 | 87.02 | 0.135538 |
| 11 | Ta2O5 | 1 | 2.13255 | 0 | 0.131869 | 39.7 | 0.061836 |
| 12 | SiO2 | 1 | 1.45677 | 0 | 0.171547 | 75.6 | 0.117758 |
| 13 | Ta2O5 | 1 | 2.13255 | 0 | 0.192364 | 57.91 | 0.090204 |
| 14 | SiO2 | 1 | 1.45677 | 0 | 0.189303 | 83.43 | 0.129948 |
| 15 | Ta2O5 | 1 | 2.13255 | 0 | 0.123316 | 37.12 | 0.057826 |
| 16 | SiO2 | 1 | 1.45677 | 0 | 0.167358 | 73.76 | 0.114883 |
| 17 | Ta2O5 | 1 | 2.13255 | 0 | 0.252444 | 76 | 0.118377 |
| 18 | SiO2 | 1 | 1.45677 | 0 | 0.303566 | 133.78 | 0.208383 |
| 19 | Ta2O5 | 1 | 2.13255 | 0 | 0.161404 | 48.59 | 0.075686 |
| 20 | SiO2 | 1 | 1.45677 | 0 | 0.167027 | 73.61 | 0.114656 |
| 21 | Ta2O5 | 1 | 2.13255 | 0 | 0.20586 | 61.97 | 0.096533 |
| 22 | SiO2 | 1 | 1.45677 | 0 | 0.316254 | 139.37 | 0.217093 |
| 23 | Ta2O5 | 1 | 2.13255 | 0 | 0.170089 | 51.21 | 0.079759 |
| 24 | SiO2 | 1 | 1.45677 | 0 | 0.147961 | 65.21 | 0.101568 |
| 25 | Ta2O5 | 1 | 2.13255 | 0 | 0.154825 | 46.61 | 0.072601 |
| 26 | SiO2 | 1 | 1.45677 | 0 | 0.175192 | 77.21 | 0.120261 |
| 27 | Ta2O5 | 1 | 2.13255 | 0 | 0.359868 | 108.34 | 0.16875 |
| 28 | SiO2 | 1 | 1.45677 | 0 | 0.221007 | 97.4 | 0.151711 |
| 29 | Ta2O5 | 1 | 2.13255 | 0 | 0.238037 | 71.66 | 0.111621 |
| 30 | SiO2 | 1 | 1.45677 | 0 | 0.184722 | 81.41 | 0.126803 |
| 31 | Ta2O5 | 1 | 2.13255 | 0 | 0.1995 | 60.06 | 0.09355 |
| 32 | SiO2 | 1 | 1.45677 | 0 | 0.224012 | 98.72 | 0.153773 |
| 33 | Ta2O5 | 1 | 2.13255 | 0 | 0.313059 | 94.25 | 0.146801 |
| 34 | SiO2 | 1 | 1.45677 | 0 | 0.229717 | 101.24 | 0.157689 |
| 35 | Ta2O5 | 1 | 2.13255 | 0 | 0.185005 | 55.7 | 0.086753 |
| 36 | SiO2 | 1 | 1.45677 | 0 | 0.197956 | 87.24 | 0.135887 |
| 37 | Ta2O5 | 1 | 2.13255 | 0 | 0.251871 | 75.83 | 0.118108 |
| 38 | SiO2 | 1 | 1.45677 | 0 | 0.264637 | 116.63 | 0.181661 |
| 39 | Ta2O5 | 1 | 2.13255 | 0 | 0.256294 | 77.16 | 0.120182 |
| 40 | SiO2 | 1 | 1.45677 | 0 | 0.212853 | 93.8 | 0.146113 |
| 41 | Ta2O5 | 1 | 2.13255 | 0 | 0.343003 | 103.26 | 0.160842 |
| 42 | SiO2 | 1 | 1.45677 | 0 | 0.151193 | 66.63 | 0.103787 |
| 43 | Ta2O5 | 1 | 2.13255 | 0 | 0.210843 | 63.47 | 0.098869 |
| 44 | SiO2 | 1 | 1.45677 | 0 | 0.345394 | 152.22 | 0.237096 |
| 45 | Ta2O5 | 1 | 2.13255 | 0 | 0.322203 | 97 | 0.151088 |
| 46 | SiO2 | 1 | 1.45677 | 0 | 0.236534 | 104.24 | 0.162369 |
| 47 | Ta2O5 | 1 | 2.13255 | 0 | 0.368381 | 110.9 | 0.172743 |
| 48 | SiO2 | 1 | 1.45677 | 0 | 0.099438 | 43.82 | 0.068259 |
| 49 | Ta2O5 | 1 | 2.13255 | 0 | 0.369423 | 111.21 | 0.173231 |
| 50 | SiO2 | 1 | 1.45677 | 0 | 0.128777 | 56.75 | 0.088399 |
| 51 | Ta2O5 | 1 | 2.13255 | 0 | 0.386057 | 116.22 | 0.181031 |
| 52 | SiO2 | 1 | 1.45677 | 0 | 0.182882 | 80.6 | 0.12554 |
| 53 | Ta2O5 | 1 | 2.13255 | 0 | 0.411772 | 123.96 | 0.193089 |
| 54 | SiO2 | 1 | 1.45677 | 0 | 0.196865 | 86.76 | 0.135138 |
| 55 | Ta2O5 | 1 | 2.13255 | 0 | 0.433882 | 130.62 | 0.203457 |
| 56 | SiO2 | 1 | 1.45677 | 0 | 0.223993 | 98.71 | 0.153761 |
| 57 | Ta2O5 | 1 | 2.13255 | 0 | 0.4611 | 138.81 | 0.21622 |
| 58 | SiO2 | 1 | 1.45677 | 0 | 0.162307 | 71.53 | 0.111416 |
| 59 | Ta2O5 | 1 | 2.13255 | 0 | 0.173259 | 52.16 | 0.081245 |
| 60 | SiO2 | 1 | 1.45677 | 0 | 0.177951 | 78.42 | 0.122155 |
| 61 | Ta2O5 | 1 | 2.13255 | 0 | 0.393062 | 118.33 | 0.184316 |
| 62 | SiO2 | 1 | 1.45677 | 0 | 0.216993 | 95.63 | 0.148955 |
| 63 | Ta2O5 | 1 | 2.13255 | 0 | 0.330572 | 99.52 | 0.155013 |
| 64 | SiO2 | 1 | 1.45677 | 0 | 0.295264 | 130.12 | 0.202685 |
| 65 | Ta2O5 | 1 | 2.13255 | 0 | 0.366086 | 110.21 | 0.171666 |
| 66 | SiO2 | 1 | 1.45677 | 0 | 0.323567 | 142.6 | 0.222113 |
| 67 | Ta2O5 | 1 | 2.13255 | 0 | 0.360054 | 108.39 | 0.168838 |
| 68 | SiO2 | 1 | 1.45677 | 0 | 0.297485 | 131.1 | 0.204209 |
| 69 | Ta2O5 | 1 | 2.13255 | 0 | 0.368612 | 110.97 | 0.172851 |
| 70 | SiO2 | 1 | 1.45677 | 0 | 0.281457 | 124.04 | 0.193207 |
| 71 | Ta2O5 | 1 | 2.13255 | 0 | 0.389269 | 117.19 | 0.182537 |
| 72 | SiO2 | 1 | 1.45677 | 0 | 0.304088 | 134.01 | 0.208742 |
| 73 | Ta2O5 | 1 | 2.13255 | 0 | 0.361221 | 108.74 | 0.169385 |
| 74 | SiO2 | 1 | 1.45677 | 0 | 0.293142 | 129.19 | 0.201227 |
| 75 | Ta2O5 | 1 | 2.13255 | 0 | 0.331089 | 99.67 | 0.155255 |
| 76 | SiO2 | 1 | 1.45677 | 0 | 0.348471 | 153.57 | 0.239209 |
| 77 | Ta2O5 | 1 | 2.13255 | 0 | 0.364577 | 109.76 | 0.170959 |
| 78 | SiO2 | 1 | 1.45677 | 0 | 0.270152 | 119.06 | 0.185447 |
| 79 | Ta2O5 | 1 | 2.13255 | 0 | 0.343733 | 103.48 | 0.161184 |
| 80 | SiO2 | 1 | 1.45677 | 0 | 0.210208 | 92.64 | 0.144297 |
| 81 | Ta2O5 | 1 | 2.13255 | 0 | 0.370376 | 111.5 | 0.173678 |
| 82 | SiO2 | 1 | 1.45677 | 0 | 0.31286 | 137.88 | 0.214763 |
| Substrate | BK 7 | | 1.51481 | 0 | | | |

| | | | |
|---|---|---|---|
| Total Thickness | 20.72609 | 7516.63 | 11.70814 |

TABLE 2
Design: Shortpass—Backside of Filter
Reference Wavelength (nm): 1087

| | | | | | Optical | Physical | |
|---|---|---|---|---|---|---|---|
| | | Packing | Refractive | Extinction | Thickness | Thickness | Geometric |
| Layer | Material | Density | Index | Coefficient | (FWOT) | (nm) | Thickness |
| Medium | Air | | 1 | 0 | | | |
| 1 | SiO2 | 1 | 1.44936 | 0 | 0.047158 | 35.37 | 0.032537 |
| 2 | Ta2O5 | 1 | 2.1 | 0 | 0.328185 | 169.87 | 0.156279 |
| 3 | SiO2 | 1 | 1.44936 | 0 | 0.332795 | 249.59 | 0.229615 |
| 4 | Ta2O5 | 1 | 2.1 | 0 | 0.730083 | 377.9 | 0.347659 |
| 5 | SiO2 | 1 | 1.44936 | 0 | 0.098316 | 73.74 | 0.067834 |
| 6 | Ta2O5 | 1 | 2.1 | 0 | 0.257213 | 133.14 | 0.122482 |
| 7 | SiO2 | 1 | 1.44936 | 0 | 0.393134 | 294.84 | 0.271246 |
| 8 | Ta2O5 | 1 | 2.1 | 0 | 0.193938 | 100.39 | 0.092352 |
| 9 | SiO2 | 1 | 1.44936 | 0 | 0.258145 | 193.61 | 0.178109 |
| 10 | Ta2O5 | 1 | 2.1 | 0 | 0.278104 | 143.95 | 0.13243 |
| 11 | SiO2 | 1 | 1.44936 | 0 | 0.286848 | 215.13 | 0.197913 |
| 12 | Ta2O5 | 1 | 2.1 | 0 | 0.301028 | 155.82 | 0.143347 |
| 13 | SiO2 | 1 | 1.44936 | 0 | 0.229139 | 171.85 | 0.158097 |
| 14 | Ta2O5 | 1 | 2.1 | 0 | 0.216246 | 111.93 | 0.102975 |
| 15 | SiO2 | 1 | 1.44936 | 0 | 0.276757 | 207.56 | 0.19095 |
| 16 | Ta2O5 | 1 | 2.1 | 0 | 0.308741 | 159.81 | 0.147019 |
| 17 | SiO2 | 1 | 1.44936 | 0 | 0.262161 | 196.62 | 0.18088 |
| 18 | Ta2O5 | 1 | 2.1 | 0 | 0.237995 | 123.19 | 0.113331 |
| 19 | SiO2 | 1 | 1.44936 | 0 | 0.254921 | 191.19 | 0.175885 |
| 20 | Ta2O5 | 1 | 2.1 | 0 | 0.272837 | 141.23 | 0.129922 |
| 21 | SiO2 | 1 | 1.44936 | 0 | 0.27954 | 209.65 | 0.192871 |
| 22 | Ta2O5 | 1 | 2.1 | 0 | 0.280113 | 144.99 | 0.133387 |
| 23 | SiO2 | 1 | 1.44936 | 0 | 0.258728 | 194.04 | 0.178511 |
| 24 | Ta2O5 | 1 | 2.1 | 0 | 0.259037 | 134.08 | 0.123351 |
| 25 | SiO2 | 1 | 1.44936 | 0 | 0.263278 | 197.45 | 0.181651 |
| 26 | Ta2O5 | 1 | 2.1 | 0 | 0.280656 | 145.27 | 0.133646 |
| 27 | SiO2 | 1 | 1.44936 | 0 | 0.363664 | 272.74 | 0.250913 |
| 28 | Ta2O5 | 1 | 2.1 | 0 | 0.407393 | 210.87 | 0.193997 |
| 29 | SiO2 | 1 | 1.44936 | 0 | 0.34872 | 261.53 | 0.240602 |
| 30 | Ta2O5 | 1 | 2.1 | 0 | 0.295915 | 153.17 | 0.140912 |
| 31 | SiO2 | 1 | 1.44936 | 0 | 0.296472 | 222.35 | 0.204553 |
| 32 | Ta2O5 | 1 | 2.1 | 0 | 0.24109 | 124.79 | 0.114805 |
| 33 | SiO2 | 1 | 1.44936 | 0 | 0.27017 | 202.62 | 0.186406 |
| 34 | Ta2O5 | 1 | 2.1 | 0 | 0.288401 | 149.28 | 0.137334 |
| 35 | SiO2 | 1 | 1.44936 | 0 | 0.329805 | 247.35 | 0.227552 |
| 36 | Ta2O5 | 1 | 2.1 | 0 | 0.368275 | 190.63 | 0.175369 |
| 37 | SiO2 | 1 | 1.44936 | 0 | 0.386659 | 289.99 | 0.266779 |
| 38 | Ta2O5 | 1 | 2.1 | 0 | 0.329026 | 170.31 | 0.156679 |
| 39 | SiO2 | 1 | 1.44936 | 0 | 0.319912 | 239.93 | 0.220726 |
| 40 | Ta2O5 | 1 | 2.1 | 0 | 0.341577 | 176.81 | 0.162656 |
| 41 | SiO2 | 1 | 1.44936 | 0 | 0.446073 | 334.55 | 0.307772 |
| 42 | Ta2O5 | 1 | 2.1 | 0 | 0.325138 | 168.3 | 0.154828 |
| 43 | SiO2 | 1 | 1.44936 | 0 | 0.336421 | 252.31 | 0.232116 |
| 44 | Ta2O5 | 1 | 2.1 | 0 | 0.410089 | 212.27 | 0.195281 |
| 45 | SiO2 | 1 | 1.44936 | 0 | 0.4317 | 323.77 | 0.297855 |
| 46 | Ta2O5 | 1 | 2.1 | 0 | 0.354078 | 183.28 | 0.168609 |
| 47 | SiO2 | 1 | 1.44936 | 0 | 0.372739 | 279.55 | 0.257174 |
| 48 | Ta2O5 | 1 | 2.1 | 0 | 0.449103 | 232.46 | 0.213858 |
| 49 | SiO2 | 1 | 1.44936 | 0 | 0.342776 | 257.08 | 0.236501 |
| 50 | Ta2O5 | 1 | 2.1 | 0 | 0.328441 | 170.01 | 0.1564 |
| 51 | SiO2 | 1 | 1.44936 | 0 | 0.371863 | 278.89 | 0.25657 |
| 52 | Ta2O5 | 1 | 2.1 | 0 | 0.391052 | 202.42 | 0.186215 |
| 53 | SiO2 | 1 | 1.44936 | 0 | 0.366632 | 274.97 | 0.252961 |
| 54 | Ta2O5 | 1 | 2.1 | 0 | 0.362789 | 187.79 | 0.172757 |
| 55 | SiO2 | 1 | 1.44936 | 0 | 0.289342 | 217 | 0.199634 |
| Substrate | BK 7 | | 1.50636 | 0 | | | |

| | | | |
|---|---|---|---|
| Total Thickness | 17.35041 | 10959.23 | 10.08209 |

The performance of the two-sided filter is shown in Transmittance Plot 1100 with x-axis 1103 for the wavelength range of 300 nm to 1800 nm and y-axis 1102 for transmittance in percent from 0 to 100%. There are 3 plot lines in Plot 1100: solid line 1104 representing the transmittance of the band-pass filter at 0° incidence angle, dashed line 1105 representing the transmittance of the band-pass filter at 12.5° and short long line 1106 representing the transmittance of the band-pass filter at 25°. The overall bandwidth of the high transmission range of the two-sided filter of Table 1 and 2 is around 100 nm, with the high reflectance bandwidth going from 350 nm to 920 and 1050 to 1800 nm. The filter exhibits very little incidence angle shift as can be seen in the lateral displacement going from incidence angles of 0 to 25°. The angle shift is low because the incidence angles are kept low on the filter but it is also a consequence of the design algorithm used, which is partly based on teachings in U.S. Pat. No. 7,859,754“Wideband dichroic-filter design for LED-phosphor beam-combining”.

In all of the above described configurations, if a large cover glass is used, and especially because the module can be thin, a dense honeycomb structure can be used between the glass and the mirror to provide stiffness.

Depending on the use, many of the configurations described above, especially when “sky splitting” or “rotating mirrors” is employed, have “free areas” surrounding the mirrors and within the enclosure. These free areas can be used for other purposes. A couple of examples are listed below.

The free area could be used to change the look of the CPV module. Currently, almost all CPV modules look grey. This limitation could be overcome by painting the mirrored part of the substrate which is not optically active nor has any function other than the enclosure.

The free area could be used to display an advertising logo. When the size of each concentrator unit is small, an image of the cell, with a size much bigger than a single unit aperture, can be seen when looking at the concentrator normal to the aperture (at a distance greater than a few meters). The image seen is a combination of the individual cells' images created by each concentrator unit. The angular size of this image is constant (and equal to the concentrator acceptance angle). In particular, it does not depend on the distance at which one looks at the module. This is why, the cell image occupies more and more concentrator units when we increase this distance. This effect can be used to create logos or advertisements whose size is adapted to the observer distance. The particular configuration of the CCF allows creating these images for the solid angle occupied by common observers during normal operation of the CPV array. These images are created from features printed on the free area of the substrate supporting the mirror. Additionally, we can use other effects such as the Moire Effect.

There are some disadvantages in the CCF design; however; as will be shown below, these are minimal and can be overcome by novel solutions.

The heat spreader and MJ cell block part of the incoming radiation. For an FK concentrator with C_{g}=1024×, and with an acceptance angle of ±1.1 deg, only 1.8% of the aperture area is blocked. This is not a significant amount and is not a major drawback.

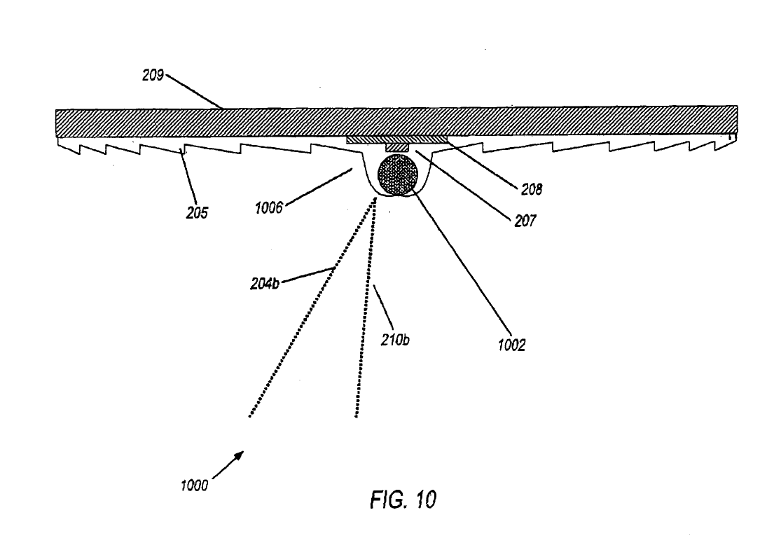

FIG. 10 shows the upper portion of CCF 1000 with optional apparatus inside the secondary lens. Front cover 209 covers Four-fold Fresnel Köhler primary refractive lens 205 molded together with four-fold secondary 1006. The POE and SOE are molded as a single part around glass ball 1002. The glass has a higher optical transmission than the silicone, increasing the efficiency of the system. Additionally, the cost of the glass ball material is much lower than the cost of the silicone it replaces, and the ball manufacturing process cost is very low too. The glass can be selected to have lower risk of UV degradation than the silicone. The refraction of light as it enters and leaves the glass ball has little effect on the paths of the light rays. Preferably, the refractive index of the ball and that of the silicone are close enough so the deflection of the rays in the silicone glass interface is small and the positioning of the ball inside the secondary cavity can be done without requiring high precision, because the optical effect of any inaccuracy is then negligible. In case the index of refractive of the silicone is significantly different than that of the ball, the ball positioning will still be robust but the optical design of the primary and secondary optics must be done taking the ball into account, that is, with the ball in its nominal position and trivially ray tracing through it as a known optical element in the design process. Also shown are Heat Spreader 208, Multi-junction Cell 207 and exemplary rays 204b and 210b.

The mirror is not a perfect reflector and some energy will be lost. All HCPV systems have optical losses. Inexpensive mirrors with efficiencies above 96% for the spectrum of interest are available. This includes conventional 2nd surface flat mirror on glass, to high reflectance solar reflective films (http:/ /solutions.3m.com/wps/portal/3M/en_US /Renewable/Energy/Product/Films/Solar_Mirror/.

A solution is to use total internal reflectors made of V grooves. In the case of FK architectures, the V grooves should be in the radial symmetry with respect to the symmetry axis of each one of the POE quadrants. The principle is taught in US Publication 2010-0002320-A1 by several of the same inventors.

For “spectrum splitting”, a dichroic or other frequency selective mirror is required and these can be expensive, especially if a custom design is needed. All-polymeric solutions are available, such as 3M Cool Mirror film, and one of these could be a good fit. 3M, and others, could also adapt an inexpensive design to fit the requirements of the new systems.

The heat load that can be adequately dissipated by the cover glass in the CFSC design is low so this design works most effectively with small solar cells. This can be seen as a disadvantage, but the combined advantages of the system have distinct advantages in many applications.

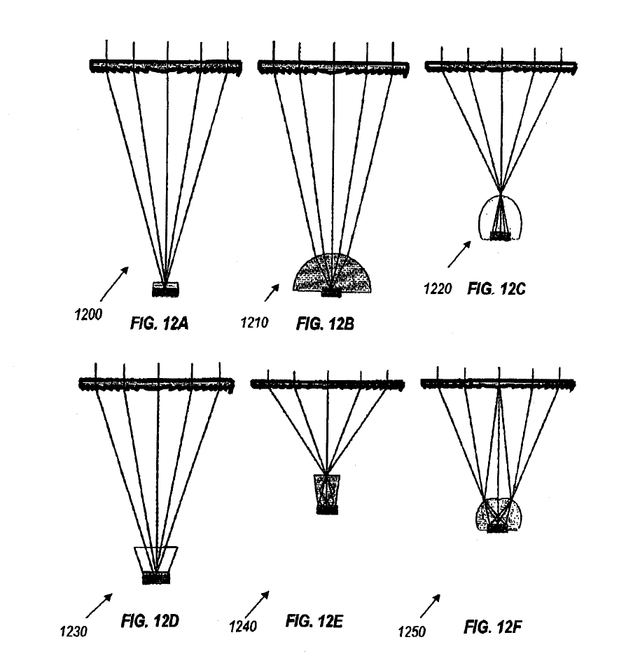

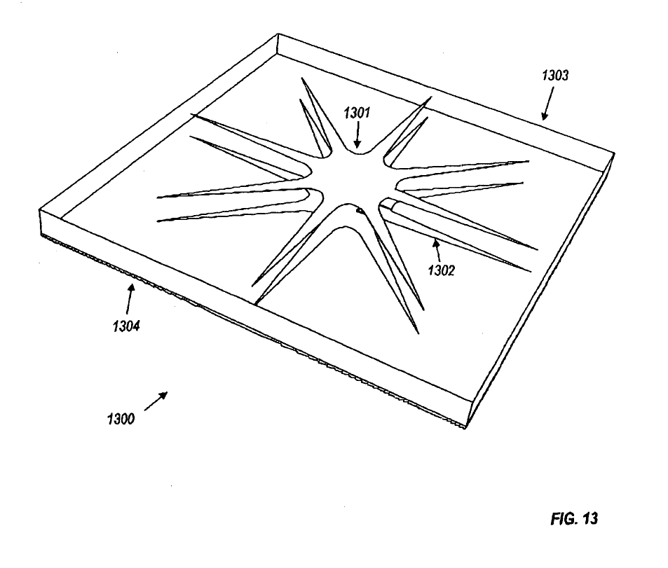

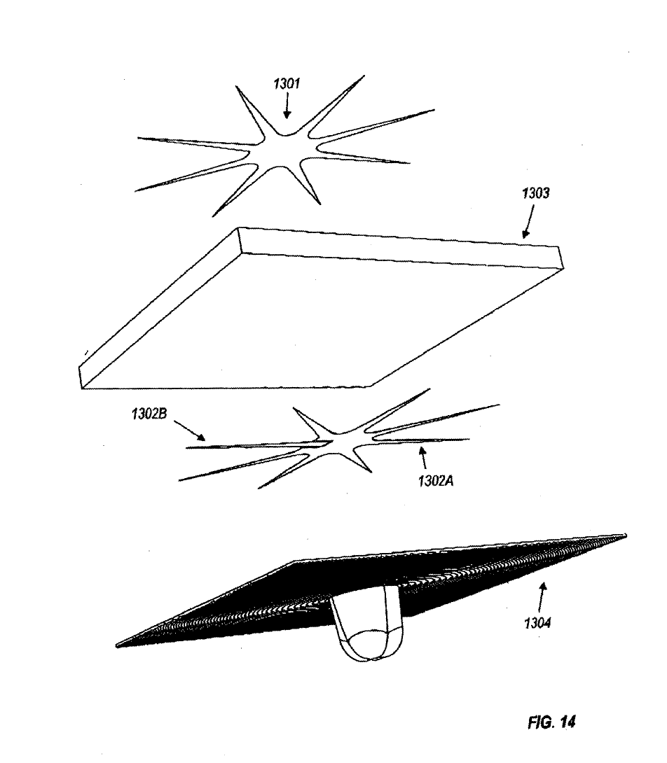

FIGS. 12A, 12B, 12C, 12D, 12E and 12F, collectively FIG. 12, shows six concentrating optical architectures of the prior art, all of which utilize either a traditional Fresnel primary lens or the Köhler Fresnel Primary shown in FIG. 1A. The Köhler type of primary is a preferred component for a CCF in combination with a Köhler secondary, as the two can be molded together as one piece without the requirement of a negative draft angle. This is possible because a sizable fraction of surface of the Köhler secondary near its base is not optically active, thus allowing the base of the secondary to be shaped as needed, as exemplified by secondary 206 in FIG. 2. FIG. 12F shows exemplary rays traveling through Concentrator 1250 of the type of FIG. 1A. Although the secondary is shown as having negative draft angles when molded onto a flat surface, it is important to note that this is not a requirement of the secondary or the system. This SOE can be modified to a shape similar to those shown in other Figures of the drawings, with positive draft angles, by altering only optically inactive parts of the surface. Looking at the other optical architectures in FIG. 12, it is useful to see which of them might also be used to derive a CCF, where the primary and secondary lens can be molded as one piece and ideally without any negative draft angles on the secondary.

FIG. 12A shows concentrator 1200 with a Fresnel primary and no secondary. If we employ the same rules used in the derivation of FIG. 1B from FIG.1A, the PV cell could reside on the front cover. And a flat dielectric cover could be molded over the PV cell together with the Fresnel primary as one piece with no negative draft angles for the mold. However, this type of concentrator has a very poor acceptance angle, which typically limits it to operate at a lower concentration ratio than the type of FIG. 12F.

FIG. 12B shows concentrator 1210 with a Fresnel primary and a spherical refractive secondary lens. If the lower portion of this architecture were mirrored up then the spherical lens would reside in the right location. But the performance of Concentrator 1210 is not as good as some of the others in FIG. 12.

FIG. 12C shows Concentrator 1220 with a Fresnel primary and a Silo lens. It is composed of a Fresnel lens primary optic and a refractive secondary in a Köhler configuration: The Fresnel lens primary images the sun onto the secondary lens, which in turn images the square primary onto a square solar cell. It also shares another characteristic with the preferred configuration in FIG. 12F in that the secondary does not require an optically active reentrant surface. However, the configuration in FIG. I 2F has four separate channels while the configuration in FIG. 12C has only one. For that reason, the CAP of the configuration in FIG. 12F is higher than that of the configuration in FIG. 12C.

FIG. 12D shows Concentrator 1230 with a Fresnel primary and an open reflector secondary. If the lower section of Concentrator 1230 was mirrored upward then the open reflector would be proximate the pv cell. In order to have a mold which without negative draft, so as to be moldable as one piece with the primary lens, dielectric material would have to fill in the gap between the primary and secondary to create a female void in the shape of the reflector. Then the inside surface of that void would need to be metalized. This would complicate the manufacturing process.

FIG. 12E shows Concentrator 1240 with a Fresnel primary and a kaleidoscope secondary. If this architecture is mirrored then the kaleidoscope would reside next to the PV cell. However, if the kaleidoscope is tapered then it will not be possible to mold the secondary with the primary as one piece, because the secondary would have reentrant surfaces. And if the secondary is not tapered then it would still not be possible to mold the two parts as one piece as all the surfaces of the kaleidoscope operate by TIR. And if these surfaces were in contact with another dielectric material TIR would not work. And the only way to get around this is to metalize the outside of the surfaces of the secondary and then fill in the void with the primary, a very difficult and impractical process.

Based on the above analysis the best architecture for the CCF of the six in FIG. 12 is Concentrator 1250 of FIG. 12F as it has a dielectric secondary (which may be the same material as the primary) does not have reentrant surfaces (and as such the primary and secondary optical elements may be molded as one part) and it has the highest CAP of all the configurations show, ensuring the best performance.

FIG. 13 shows a configuration 1300 in which a top heat spreader 1301 lays on top of glass cover 1303 and heat spreader 1302 lays below said glass cover. Below this stack is optic 1304. Heat spreaders 1301 and 1302 have the same shape when seen from the sun, and therefore bottom heat spreader 1302 does not increase the shading produced by top heat spreader 1301. The heat spreaders 1301, 1302 may be formed by silk screening a conductive material onto the glass cover 1303. One suitable conductive material is Heraeus C 8830 low temperature silver conductor paste, applied in a thickness of 100 to 150 microns. The heat spreader 1301 on the front surface of the glass cover 1303 may be covered with any suitable transparent coating to prevent tarnishing of the silver and mechanical damage to the heat spreader in use. The flat shape of the silk-screened heat spreader 1301 is advantageous because it results in only a very slight bulge on the surface of the device, which does not tend to accumulate dirt or debris, or to obstruct cleaning of the front of the device. On the inside, the similarly flat shape of the heat spreader 1302 is advantageous because it does not tend to interfere with the molding of the silicone onto the glass to form the Fresnel lens.

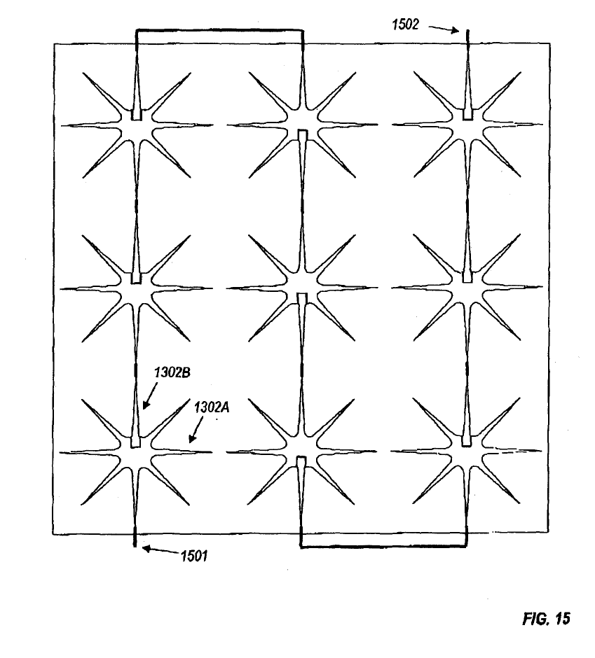

FIG. 14 shows an exploded view of the configuration in FIG. 13.

The mirror 113, 203, etc., and other structures associated with the mirror are omitted from FIG. 13 in the interests of simplicity. The sub-assembly shown in FIG. 13 may be used as a modification to any of the devices previously described.

The top heat spreader 1301 is not provided with any metallic connection through the cover plate 1303. The cover plate 1303 is uninterrupted, in the interests of mechanical integrity and weather-tightness. Surprisingly, enough heat can be conducted from the lower or back heat spreader 1302 through the glass to the top or front heat spreader 1301 for the top heat spreader to be useful. The top heat spreader can conduct the heat that it receives from the bottom heat spreader 1302 radially outwards, and can either dissipate that heat directly to the ambient environment by radiation or by conduction/convection into the atmosphere, or can return the heat to the outer surface of the glass cover plate 1303 for similar dissipation. This arrangement is valuable in some embodiments, where the thickness of the lower heat spreader 1302 (and therefore its ability to conduct heat) is limited because it is desirable to embed the lower heat spreader 1302 completely in the silicone molding of the primary lens 109a, etc., and it is desirable to keep the primary lens 109a, etc. thin, because silicone is both expensive and not perfectly transparent.

In embodiments (see FIG. 8) where the Fresnel lens is in distinct sections, it may be desirable to align the arms of the heat spreaders 1301, 1302 with the boundaries between the sections of the Fresnel lens, because superimposing features that will interrupt the light entering the system reduces, the total amount of light interrupted.

As illustrated in FIG. 15, and as discussed in our earlier WO 2011/066286, the arms of the heat spreader may be used as the electrical conductors from the photovoltaic cell 105a, etc. In the interests of conciseness, that description is not repeated here, but one arm 1302A of the heat spreader 1302 is symbolically shown as electrically isolated from the remainder 1302B of the heat spreader. FIG. 15 shows one way in which the different solar cells in an array can be connected in series using the arms of the bottom heat spreaders. The whole assembly has two external terminals 1501 and 1502, by which it can be connected to external circuitry.

The top heat spreader 1301 is not involved in the electrical circuitry, because it is isolated by the glass cover 1303, but may be identical to the bottom heat spreader 1302, so that only one silk-screening mask is needed. Because the heat is transferred vertically through the glass from the bottom heat spreader 1302, the isolating gap between the sections corresponding to the gap between sections 1302A and 1302B does not significantly detract from the performance of the heat spreader.

It will be appreciated that a heat spreader on only one surface of the glass plate 1303 may be used. However, because the width of the arms of the heat spreader may be limited, in order to avoid blocking too much of the incoming sunlight, that may require a thicker heat spreader to provide sufficient heat conduction. As noted above, there are advantages to a thin heat spreader. In particular, if a thick heat spreader, more similar to those in our earlier WO 2011/066286, is used on the underside of the glass, care may be needed to ensure that the optic is molded without distortions or bubbles.

The embodiments have been shown in the drawings with the direction from which incident light is expected to arrive upwards, and that direction has been variously referred to as “up” and “front.” These and other expressions of orientation or direction are not limiting. The HCPV devices, when used as solar concentrators, will preferably be oriented with that direction towards the sun, which depends on geographical location and time of day and year. When used for other purposes, the devices may be in other orientations. When not in use, the devices may be parked, stored, and shipped in any convenient orientation.

Various embodiments have been described, and various ways in which features of different embodiments may be combined have been mentioned. However, the skilled reader will see how other features of the described embodiments may be combined, and other ways in which the embodiments may be modified.

The preceding description of the presently contemplated best mode of practicing the invention is therefore not to be taken in a limiting sense, but is made merely for the purpose of describing the general principles of the invention. The full scope of the invention should be determined with reference to the Claims.

We claim:

1. A high concentration photovoltaic device, comprising:
a Fresnel lens having a front side and a back side;
a mirror behind the Fresnel lens and facing the Fresnel lens;
a secondary lens unitary with the Fresnel lens and facing the mirror; and
a photovoltaic cell in front of the secondary lens and facing the mirror through the secondary lens;
wherein two optical elements of said device form a Köhler integrator between a remote source in front of the Fresnel lens and the photovoltaic cell as a target.

2. The device of claim 1, wherein the unitary Fresnel lens and secondary lens are formed on the back of a cover plate.

3. The device of claim 2, wherein the cover plate is glass and the unitary Fresnel lens and secondary lens are of plastic molded onto the cover plate, and the photovoltaic cell is embedded in the plastic between the secondary lens and the cover plate.

4. The device of claim 2, further comprising a heat spreader between the photovoltaic cell and the cover plate, in thermal contact with the photovoltaic cell and the cover plate.

5. The device of claim 4, wherein the heat spreader further comprises arms radiating from the photovoltaic cell, the arms being in contact with a back side of the cover plate along the length of the arms.

6. The device of claim 4, further comprising a second heat spreader on a front side of the cover plate, the second heat spreader having arms in contact with the back side of the cover plate along the length of the arms, the arms of the second heat spreader being aligned in front of the arms of the first heat spreader and the second heat spreader being separated from the first heat spreader by the cover plate, so that at least some of the heat from the first heat spreader is conducted to the second heat spreader through the cover plate, is conducted radially outwards on the front side of the cover plate by the arms of the second heat spreader, and is returned to the cover plate by the second heat spreader for dissipation into the external environment.

7. The device of claim 1, further comprising a third lens in front of the mirror.

8. The device of claim 6, wherein two of the Fresnel lens, the secondary lens, and the third lens form the Köhler integrator.

9. The device of claim 1, wherein the mirror is mounted tiltably relative to the Fresnel lens.

10. The device of claim 1, wherein the mirror is a frequency selective partially transmissive mirror, and the device further comprises a second photovoltaic cell behind the mirror.

11. The device of claim 9, wherein the photovoltaic cell in front of the secondary lens is a multi junction photovoltaic cell and the second photovoltaic cell is a single-junction photovoltaic cell.

12. The device of claim 10, wherein the mirror is a band-pass mirror comprising a long-pass mirror and a short-pass mirror.

13. The device of claim 11, wherein the long-pass mirror is partially transmissive at wavelengths longer than the pass-band of the band-pass mirror, the short-pass mirror is partially transmissive at wavelengths shorter than the pass-band of the band-pass mirror, and the two mirrors are matched so that wavelengths outside the pass-band at which each mirror is partially transmissive are wavelengths at which the other mirror is substantially completely reflective.

14. The device of claim 1, wherein the mirror is smaller in area than the Fresnel lens, further comprising an additional photovoltaic cell behind an outer part of the Fresnel lens outside the mirror, operative in use to generate electricity from light incident from directions other than directly in front of the Fresnel lens.
